(19) United States
(12) Patent Application Publication
(10) Pub. No.: US 2025/0280706 A1
(43) Pub. Date: Sep. 4, 2025

(54) DISPLAY DEVICE

(71) Applicant: LG Display Co., Ltd., Seoul (KR)

(72) Inventors: Seonhee LEE, Paju-si (KR); Sukhyun KANG, Paju-si (KR)

(73) Assignee: LG Display Co., Ltd., Seoul (KR)

(21) Appl. No.: 18/953,572

(22) Filed: Nov. 20, 2024

(30) Foreign Application Priority Data
Feb. 29, 2024 (KR) 10-2024-0029461

(51) Int. Cl. H10K 59/80; H10K 59/122; H10K 59/124

(52) U.S. Cl. CPC H10K 59/873; H10K 59/122; H10K 59/124

(57) ABSTRACT

In a display device, a first metal layer which has an opening is located in an intermediate area between a display area and an opening area, and an organic encapsulation layer overlaps the opening of the first metal layer in at least a partial area. Therefore, it is possible to provide a display device capable of reducing foreign substances generated in the course of a process and thereby improving reliability.

### CROSS-REFERENCE TO RELATED APPLICATION

This application claims the benefit of and priority to Korean Patent Application No. 10-2024-0029461 filed on Feb. 29, 2024, the entire contents of which are incorporated herein by reference for all purposes as if fully set forth herein.

### BACKGROUND

### 1. Technical Field

Embodiments of the present disclosure relate to a display device.

### 2. Description of the Related Art

As technology advances, a display device may provide a photographing function and various detection functions in addition to an image display function.

To this end, the display device should include an optical electronic device (also referred to as a light reception device or a sensor) such as a camera and a detection sensor.

Since the optical electronic device should receive light from the front surface of the display device, the optical electronic device should be installed at a location that is advantageous for reception of light.

Therefore, the camera (a camera lens) and the detection sensor cannot help but be installed on the front surface of the display device so as to be exposed.

Due to this fact, the bezel of a display panel is widened, or a notch or a physical hole is formed in the display area of the display panel and the camera or the detection sensor is installed therein.

Accordingly, as the optical electronic device, such as a camera and a detection sensor, which performs a predetermined function by receiving light from the front surface is provided in the display device, high transmittance of the display device may be required.

The description of the related art should not be assumed to be prior art merely because it is mentioned in or associated with this section. The description of the related art includes information that describes one or more aspects of the subject technology, and the description in this section does not limit the invention.

### SUMMARY

In the art, there is an attempt to secure reliability by forming an undercut structure around a channel hole where a camera is installed in a display panel to cut a light emitting layer and contacting an encapsulation layer to prevent the penetration of moisture particles.

However, there is a problem that an additional process is required to form the undercut structure. Accordingly, the inventors of the present disclosure have invented a display device capable of securing reliability by reducing foreign substances generated in the course of a process while realizing process optimization.

Embodiments of the present disclosure are directed to providing a display device capable of reducing foreign substances generated in the course of a process.

Embodiments of the present disclosure are directed to providing a display device capable of realizing process optimization while ensuring the reliability of a display panel.

According to embodiments of the present disclosure, a display device may include: a substrate; an opening area; a display area which surrounds the opening area; an intermediate area between the opening area and the display area; an insulating layer located in the intermediate area on the substrate; a first metal layer located on the insulating layer and including at least one first opening, the at least one first opening being located in the intermediate area; a second metal layer located on the first metal layer in the intermediate area and including at least one second opening, the at least one second opening being disposed in an area including an area overlapping the at least one first opening; and an organic encapsulation layer located on the insulating layer and at least partially overlapping the at least one first opening.

According to embodiments of the present disclosure, a display device may include: a substrate; an opening area; a display area which surrounds the opening area; an intermediate area between the opening area and the display area; an outer area which surrounds an outside of the display area; at least one first dam located on the substrate and disposed in the outer area; and at least one second dam located on the substrate, disposed in the intermediate area and including a dummy electrode which is located at a same layer as a cathode electrode disposed in the display area.

According to embodiments of the present disclosure, a display device may include: a substrate; an opening area; a display area which surrounds the opening area; an intermediate area between the opening area and the display area; an insulating layer located in the intermediate area on the substrate; an encapsulation layer located on the insulating layer, located in the intermediate area, and including a first part which includes an organic encapsulation layer and a second part which does not include the organic encapsulation layer; a first metal layer located in the first part and located between the insulating layer and the organic encapsulation layer; and a second metal layer located in the first part and located between the first metal layer and the organic encapsulation layer.

According to the embodiments of the present disclosure, it is possible to provide a display device capable of reducing foreign substances generated in the course of a process.

According to the embodiments of the present disclosure, by reducing foreign substances generated in the course of a process, it is possible to provide a display device capable of realizing process optimization while ensuring the reliability of a display panel.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a plan view of a display device according to embodiments of the present disclosure.

FIG. 2 is a system configuration diagram of the display device according to the embodiments of the present disclosure.

FIG. 3 is an equivalent circuit diagram of a subpixel in the display device according to the embodiments of the present disclosure.

FIGS. 4A and 4B are plan views showing a part of a display panel according to the embodiments of the present disclosure.

FIGS. 5A to 5D are cross-sectional views taken along the line I-I′ of FIG. 4A.

FIG. 6 is a cross-sectional view taken along the line II-II′ of FIG. 4B.

FIG. 7 is a cross-sectional view taken along the line III-III′ of FIG. 4A.

FIG. 8 is an enlarged sectional view of the part A of FIG. 5A.

FIGS. 9A to 9C are plan views showing at least one dam shown in FIG. 4A.

FIGS. 10A to 10C are cross-sectional views simply showing a process for forming a partial area of the display panel according to the embodiments of the present disclosure.

FIGS. 11A to 11C are plan views simply showing a process for forming a partial area of the display panel according to the embodiments of the present disclosure.

FIGS. 12A to 12D are cross-sectional views simply showing a process for forming a partial area of the display panel according to the embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to accompanying drawings.

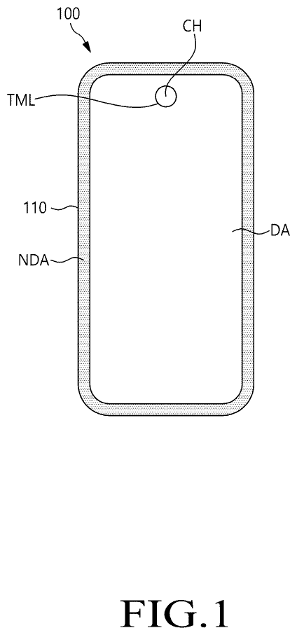

FIG. 1 is a plan view of a display device 100 according to embodiments of the present disclosure.

Referring to FIG. 1, the display device 100 according to the embodiments of the present disclosure may include a display panel 110 which displays an image and at least one channel hole CH.

The display panel 110 may include a display area DA where an image is displayed and a non-display area NDA where an image is not displayed.

In the display area DA, a plurality of subpixels may be disposed, and various signal lines for driving the plurality of subpixels may be disposed.

The non-display area NDA may be an area outside the display area DA.

In the non-display area NDA, various signal lines may be disposed, and various driving circuits may be connected.

The non-display area NDA may be bent to be invisible on a front surface or may be covered by a case (not shown).

The non-display area NDA may be referred to as a bezel or a bezel area.

Referring to FIG. 1, in the display device 100 according to the embodiments of the present disclosure, the channel hole CH may be formed by cutting along a cutting line TML.

Light may enter the front surface (or the viewing surface) of the display panel 110, and may be transferred through the channel hole CH of the display panel 110 to at least one optical electronic device which is located under the display panel 110 (or on a surface opposite to the viewing surface).

The at least one optical electronic device may be a device which receives light transmitted through the display panel 110 and performs a predetermined function according to received light.

For example, the at least one optical electronic device may include at least one of a photographing device such as a camera (an image sensor) and a detection sensor such as a proximity sensor and an illuminance sensor.

The illuminance sensor may be an ambient light sensor, but is not limited thereto.

In a state in which the display device 100 is turned off, ambient light for the display device 100 may be detected using the illuminance sensor, and the luminance of a screen outputted through the display panel 110 may be adjusted according to the brightness of ambient light.

Although the channel hole CH is depicted as having a circular structure, the shape of the channel hole CH according to the embodiments of the present disclosure is not limited thereto.

The channel hole CH may have various shapes such as circular, oval, quadrangular, hexagonal and octagonal shapes.

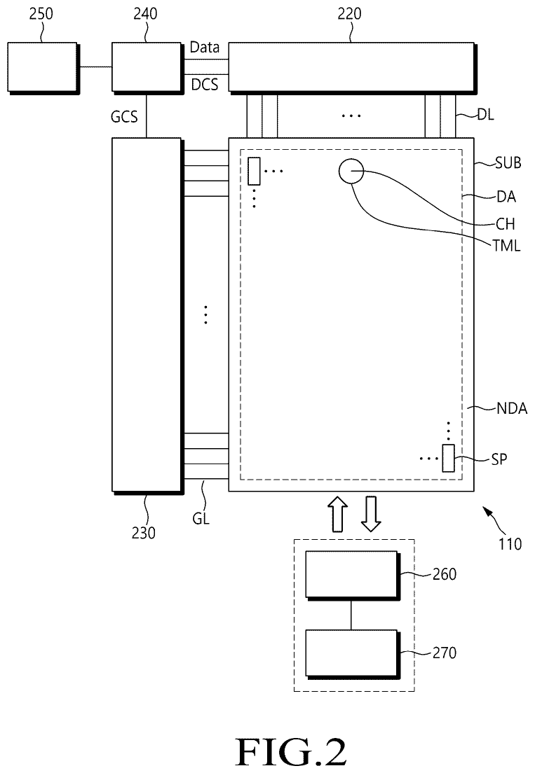

FIG. 2 is a system configuration diagram of the display device 100 according to the embodiments of the present disclosure.

Referring to FIG. 2, the display device 100 may include the display panel 110 and a display driving circuit as components for displaying an image.

The display driving circuit as a circuit for driving the display panel 110 may include a data driving circuit 220, a gate driving circuit 230 and a display controller 240.

The display panel 110 may include the display area DA in which an image is displayed and the non-display area NDA in which an image is not displayed.

The non-display area NDA may be an area outside the display area DA, and may also be referred to as a bezel area.

The entirety or a part of the non-display area NDA may be an area which is visible on the front surface of the display device 100 or an area which is bent and thus is not visible on the front surface of the display device 100.

The display panel 110 may include a substrate SUB and a plurality of subpixels SP which are disposed on the substrate SUB.

In order to drive the plurality of subpixels SP, the display panel 110 may further include various types of signal lines.

The display device 100 according to the embodiments of the present disclosure may be a liquid crystal display device or the like, or may be a self-emissive display device in which the display panel 110 self-emits light.

When the display device 100 according to the embodiments of the present disclosure is a self-emissive display device, each of the plurality of subpixels SP may include a light emitting element.

For example, the display device 100 according to the embodiments of the present disclosure may be an organic light emitting display device in which a light emitting element is implemented with an organic light emitting diode (OLED).

For another example, the display device 100 according to the embodiments of the present disclosure may be an inorganic light emitting display device in which a light emitting element is implemented with an inorganic-based light emitting diode.

For still another example, the display device 100 according to the embodiments of the present disclosure may be a quantum dot display device in which a light emitting element is implemented with quantum dots as semiconductor crystals which self-emit light.

The structure of each of the plurality of subpixels SP may vary depending on the type of the display device 100.

For example, when the display device 100 is a self-emissive display device in which each subpixel SP self-emits light, each subpixel SP may include a self-emissive light emitting element, at least one transistor and at least one capacitor.

For example, the various types of signal lines may include a plurality of data lines DL which transfer data signals (also referred to as data voltages or image signals) and a plurality of gate lines GL which transfer gate signals (also referred to as scan signals).

The plurality of data lines DL and the plurality of gate lines GL may intersect each other.

Each of the plurality of data lines DL may be disposed to extend in a first direction.

Each of the plurality of gate lines GL may be disposed to extend in a second direction.

The first direction may be a column direction, and the second direction may be a row direction.

Alternatively, the first direction may be a row direction, and the second direction may be a column direction.

The data driving circuit 220 as a circuit for driving the plurality of data lines DL may output data signals to the plurality of data lines DL.

The gate driving circuit 230 as a circuit for driving the plurality of gate lines GL may output gate signals to the plurality of gate lines GL.

The display controller 240 as a device for controlling the data driving circuit 220 and the gate driving circuit 230 may control driving timing for the plurality of data lines DL and driving timing for the plurality of gate lines GL.

The display controller 240 may supply to the data driving circuit 220 a data driving control signal DCS for controlling the data driving circuit 220, and may supply to the gate driving circuit 230 a gate driving control signal GCS for controlling the gate driving circuit 230.

The display controller 240 may receive input image data from a host system 250, and may supply image data Data to the data driving circuit 220 on the basis of the input image data.

The data driving circuit 220 may supply data signals to the plurality of data lines DL according to the driving timing control of the display controller 240.

The data driving circuit 220 may receive the image data Data of a digital type from the display controller 240, may convert the received image data Data into data signals of an analog type, and may output the data signals to the plurality of data lines DL.

The gate driving circuit 230 may supply gate signals to the plurality of gate lines GL according to the timing control of the display controller 240.

The gate driving circuit 230 may be supplied with a first gate voltage corresponding to a turn-on level voltage and a second gate voltage corresponding to a turn-off level voltage along with various gate driving control signals GCS, may generate gate signals, and may supply the generated gate signals to the plurality of gate lines GL.

For example, the data driving circuit 220 may be connected to the display panel 110 in a tape automated bonding (TAB) method, may be connected to bonding pads of the display panel 110 in a chip-on-glass (COG) or chip-on-panel (COP) method, or may be connected to the display panel 110 by being implemented in a chip-on-film (COF) method.

The gate driving circuit 230 may be connected to the display panel 110 in a tape automated bonding (TAB) method, may be connected to the bonding pads of the display panel 110 in a chip-on-glass (COG) or chip-on-panel (COP) method, or may be connected to the display panel 110 according to a chip-on-film (COF) method.

Alternatively, the gate driving circuit 230 may be formed in the non-display area NDA of the display panel 110 in a gate-in-panel (GIP) type.

The gate driving circuit 230 may be disposed on a substrate or may be connected to the substrate.

Namely, in the case of the GIP type, the gate driving circuit 230 may be disposed in the non-display area NDA of the substrate.

In the case of the chip-on-glass (COG) type or the chip-on-film (COF) type, the gate driving circuit 230 may be connected to the substrate.

At least one driving circuit of the data driving circuit 220 and the gate driving circuit 230 may be disposed in the display area DA of the display panel 110.

For example, at least one driving circuit of the data driving circuit 220 and the gate driving circuit 230 may be disposed not to overlap the subpixels SP, or may be disposed to partially or entirely overlap the subpixels SP.

The data driving circuit 220 may be connected to one side (e.g., the upper side or the lower side) of the display panel 110.

Depending on a driving method, a panel design method, etc., the data driving circuit 220 may be connected to both sides (e.g., the upper side and the lower side) of the display panel 110, or may be connected to at least two sides of the four sides of the display panel 110.

The gate driving circuit 230 may be connected to one side (e.g., the left side or the right side) of the display panel 110.

Depending on a driving method, a panel design method, etc., the gate driving circuit 230 may be connected to both sides (e.g., the left side and the right side) of the display panel 110, or may be connected to at least two sides of the four sides of the display panel 110.

The display controller 240 may be implemented as a component separate from the data driving circuit 220, or may be implemented as an integrated circuit by being integrated with the data driving circuit 220.

The display controller 240 may be a timing controller which is used in general display technology, may be a control device which includes a timing controller and is capable of further performing other control functions, may be a control device which is different from a timing controller, or may be a circuit in a control device.

The display controller 240 may be implemented by various circuits or electronic parts such as an integrated circuit (IC), a field programmable gate array (FPGA), an application specific integrated circuit (ASIC) and a processor.

The display controller 240 may be mounted on a printed circuit board, a flexible printed circuit or the like, and may be electrically connected to the data driving circuit 220 and the gate driving circuit 230 through the printed circuit board, the flexible printed circuit or the like.

The display controller 240 may transmit and receive signals to and from the data driving circuit 220 according to at least one predetermined interface.

For example, the interface may include a low voltage differential signaling (LVDS) interface, an EPI interface, a serial peripheral (SP) interface, etc.

In order to further provide a touch sensing function as well as an image display function, the display device 100 according to the embodiments of the present disclosure may include a touch sensor and a touch sensing circuit which, by sensing the touch sensor, detects whether a touch event has occurred by a touch object such as a finger or a pen or detects a touch position.

The touch sensing circuit may include a touch driving circuit 260 which generates and outputs touch sensing data by driving and sensing the touch sensor, and a touch controller 270 which is able to detect the occurrence of a touch event or detect a touch position using the touch sensing data.

The touch sensor may include a plurality of touch electrodes.

The touch sensor may further include a plurality of touch lines for electrically connecting the plurality of touch electrodes and the touch driving circuit 260.

The touch sensor may exist in the form of a touch panel outside the display panel 110, or may exist inside the display panel 110.

In the case where the touch sensor exists in the form of a touch panel outside the display panel 110, the touch sensor may be referred to as an external type.

When the touch sensor is an external type, the touch panel and the display panel 110 may be separately manufactured and be coupled during an assembly process.

The external type touch panel may include a substrate for a touch panel and a plurality of touch electrodes on the substrate for a touch panel.

When the touch sensor exists inside the display panel 110, the touch sensor may be formed on the substrate SUB together with signal lines and electrodes related with display driving during the process of manufacturing the display panel 110.

The touch driving circuit 260 may supply a touch driving signal to at least one of the plurality of touch electrodes, and may generate touch sensing data by sensing at least one of the plurality of touch electrodes.

The touch sensing circuit may perform touch sensing in a self-capacitance sensing method or a mutual-capacitance sensing method.

In the case where the touch sensing circuit performs touch sensing in the self-capacitance sensing method, the touch sensing circuit may perform touch sensing on the basis of the capacitance between each touch electrode and a touch object (e.g., a finger, a pen, etc.).

According to the self-capacitance sensing method, each of the plurality of touch electrodes may serve as both a driving touch electrode and a sensing touch electrode.

The touch driving circuit 260 may drive all or some of the plurality of touch electrodes, and may sense all or some of the plurality of touch electrodes.

In the case where the touch sensing circuit performs touch sensing in the mutual-capacitance sensing method, the touch sensing circuit may perform touch sensing on the basis of the capacitance between touch electrodes.

According to the mutual-capacitance sensing method, the plurality of touch electrodes are divided into driving touch electrodes and sensing touch electrodes.

The touch driving circuit 260 may drive the driving touch electrodes and sense the sensing touch electrodes.

The touch driving circuit 260 and the touch controller 270 included in the touch sensing circuit may be implemented as separate devices or may be implemented as a single device.

Further, the touch driving circuit 260 and the data driving circuit 220 may be implemented as separate devices or may be implemented as a single device.

The display device 100 may further include a power supply circuit which supplies various types of power to the display driving circuit and/or the touch sensing circuit.

The display device 100 according to the embodiments of the present disclosure may be a mobile terminal such as a smart phone and a tablet or a monitor or a television (TV) of various sizes. However, the display device 100 according to the embodiments of the present disclosure is not limited thereto, and may be a display of various types and various sizes capable of displaying information or an image.

The display area DA in the display panel 110 may include a normal area NA and the at least one channel hole CH.

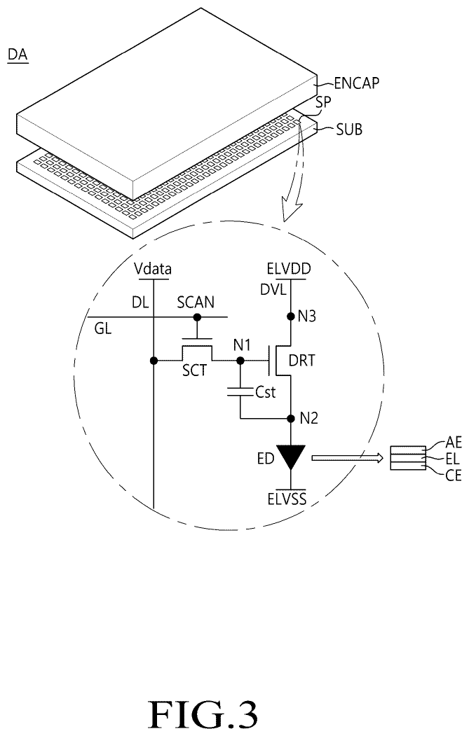

FIG. 3 is an equivalent circuit diagram of a subpixel SP in the display device 110 according to the embodiments of the present disclosure.

Each of the subpixels SP included in the display area DA of the display panel 110 may include a light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame.

The driving transistor DRT may include the first node N1 to which the data voltage Vdata may be applied, a second node N2 which is electrically connected to the light emitting element ED and a third node N3 to which a driving voltage ELVDD from a driving voltage line DVL is applied.

In the driving transistor DRT, the first node N1 may be a gate node, the second node N2 may be a source node or a drain node, and the third node N3 may be a drain node or a source node.

The light emitting element ED may include a first electrode layer AE, a light emitting layer EL and a second electrode layer CE.

The first electrode layer AE may be a pixel electrode which is disposed in each subpixel SP, and may be electrically connected to the second node N2 of the driving transistor DRT of each subpixel SP.

The second electrode layer CE may be a common electrode which is disposed in common in the plurality of subpixels SP, and may be applied with a base voltage ELVSS.

For example, the first electrode layer AE may be a pixel electrode, and the second electrode layer CE may be a common electrode.

Conversely, the first electrode layer AE may be a common electrode, and the second electrode layer CE may be a pixel electrode.

Hereinafter, for the sake of convenience in explanation, it is assumed that the first electrode layer AE is a pixel electrode and the second electrode layer CE is a common electrode.

The light emitting element ED may be an organic light emitting diode (OLED), an inorganic light emitting diode or a quantum dot (QD) light emitting element.

When the light emitting element ED is an organic light emitting diode, the light emitting layer EL in the light emitting element ED may include an organic light emitting layer which includes an organic material.

The scan transistor SCT may be on-off controlled by a scan signal SCAN which is a gate signal applied through a gate line GL, and may be electrically connected between the first node N1 of the driving transistor DRT and a data line DL.

The storage capacitor Cst may be electrically connected between the first node N1 and the second node N2 of the driving transistor DRT.

As illustrated in FIG. 3, each subpixel SP may have a 2T (transistor) 1C (capacitor) structure including two transistors DRT and SCT and one capacitor Cst. As the case may be, the subpixel SP may further include at least one transistor or may further include at least one capacitor.

The storage capacitor Cst may not be a parasitic capacitor (e.g., Cgs or Cgd) which is an internal capacitor likely to exist between the first node N1 and the second node N2 of the driving transistor DRT, but may be an external capacitor which is intentionally designed outside the driving transistor DRT.

Each of the driving transistor DRT and the scan transistor SCT may be an n-type transistor or a p-type transistor.

Each of the driving transistor DRT and the scan transistor SCT may be configured with a low-temperature polycrystalline silicon transistor.

However, the present disclosure is not limited thereto, and at least one of the driving transistor DRT and the scan transistor SCT may be configured with an oxide thin film transistor.

Because circuit elements (in particular, the light emitting element ED) in each subpixel SP are vulnerable to external moisture or oxygen, an encapsulation layer ENCAP for preventing external moisture or oxygen from penetrating into the circuit elements (in particular, the light emitting element ED) may be disposed in such a way to cover light emitting elements ED.

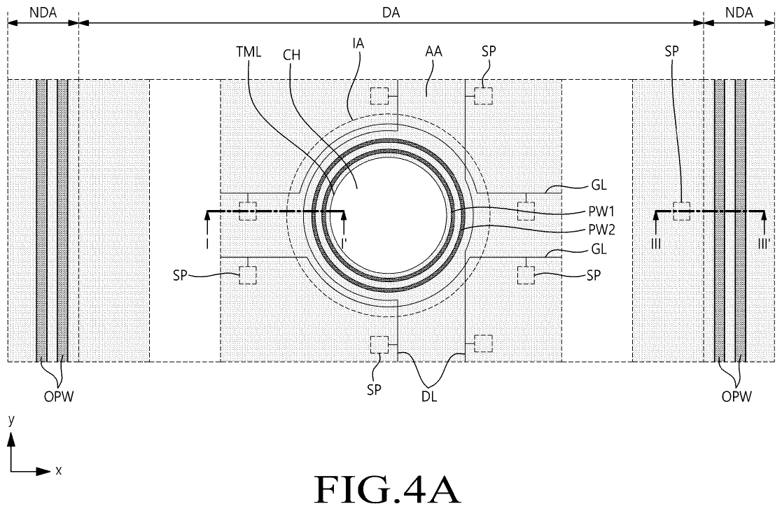

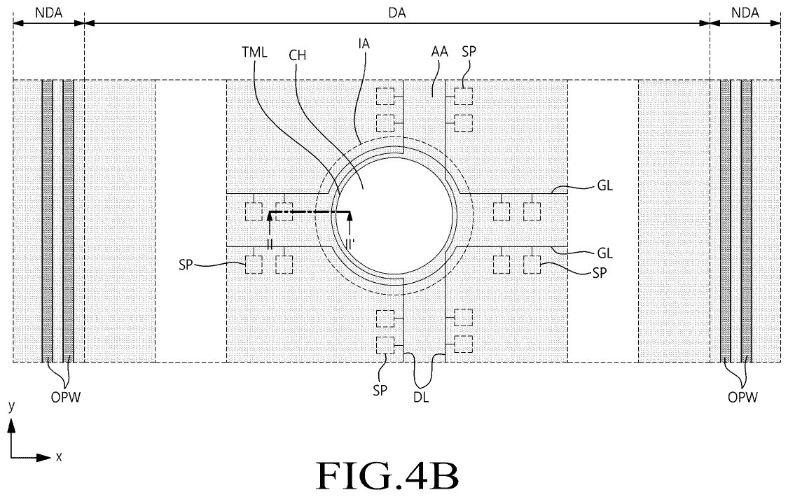

FIGS. 4A and 4B are plan views showing a part of a display panel according to the embodiments of the present disclosure.

In FIGS. 4A and 4B, only one channel hole CH is shown. However, this is for the sake of convenience in explanation, and the present disclosure is not necessarily limited thereto. There may be a plurality of channel holes CH, and the channel hole CH may correspond to at least a part of an opening area OA.

For the sake of convenience in explanation, in FIGS. 4A and 4B, the opening area OA may be referred to as the channel hole CH, but the opening area OA is not necessarily limited to the channel hole CH in one-to-one correspondence.

Referring to FIGS. 4A and 4B, subpixels SP are disposed in the display area DA, and an intermediate area IA may be located between the subpixels SP and the channel hole CH.

Subpixels SP which are adjacent to the channel hole CH may be disposed to be spaced apart from each other about the channel hole CH when viewed on a plane.

As shown in the plan views of FIGS. 4A and 4B, the subpixels SP may be disposed to be spaced apart up and down about the channel hole CH, or may be disposed to be spaced apart left and right about the channel hole CH.

Each subpixel SP uses red, green or blue light emitted from a light emitting element, and the locations of the subpixels SP shown in FIGS. 4A and 4B correspond to the locations of light emitting elements, respectively.

Therefore, the fact that the subpixels SP are disposed to be spaced apart from each other about the channel hole CH when viewed on a plane may indicate that light emitting elements are disposed to be spaced apart from each other about the channel hole CH when viewed on a plane.

Among gate lines GL and data lines DL connected to the light emitting elements of respective subpixels SP, gate lines GL and data lines DL which are adjacent to the channel hole CH may bypass the cutting line TML which is the edge of the channel hole CH.

Some data lines DL among the data lines DL which pass through the display area DA extend in a y direction to transfer data signals to subpixels SP disposed up and down with the channel hole CH interposed therebetween, but may bypass the channel hole CH along the edges of a first dam PW1 and a second dam PW2 in the intermediate area IA as shown in FIG. 4A or may bypass the channel hole CH along the cutting line TML, which is the edge of the channel hole CH, in the intermediate area IA as shown in FIG. 4B.

In addition, some gate lines GL among the gate lines GL which pass through the display area DA extend in an x direction to transfer gate signals to subpixels SP disposed left and right with the channel hole CH interposed therebetween, but may bypass the channel hole CH along the edges of the first dam PW1 and the second dam PW2 in the intermediate area IA as shown in FIG. 4A or may bypass the channel hole CH along the cutting line TML, which is the edge of the channel hole CH, in the intermediate area IA as shown in FIG. 4B.

Although FIGS. 4A and 4B show that gate lines GL bypass the channel hole CH in the intermediate area IA, this is nothing but a mere example and the present disclosure is not limited thereto.

Referring to FIGS. 4A and 4B, an outer dam OPW which surrounds the display area DA may be disposed in the non-display area NDA.

The outer dam OPW of FIGS. 4A and 4B shows an example in which the number of partition walls is two, but is not necessarily limited to the number.

Referring to FIG. 4A, in the intermediate area IA, at least one dam which is disposed to be closer to the channel hole CH than the bypass portions of the data lines DL may be located.

In this regard, FIG. 4A shows the first dam PW1 and the second dam PW2.

The first dam PW1 and the second dam PW2 may be disposed to be spaced apart from each other in the intermediate area IA as simple closed curve shapes that surround the channel hole CH.

In FIG. 4A, a case where the first dam PW1 and the second dam PW2 have ring shapes will be described as an example.

Meanwhile, referring to FIG. 4B, unlike FIG. 4A, since a dam which is disposed to be close to the channel hole CH does not exist, data lines DL and gate lines GL of FIG. 4B may be disposed closer to the channel hole CH than the data lines DL and the gate lines GL of FIG. 4A.

As the data lines DL and the gate lines GL are disposed closer to the channel hole CH, the area of the display area DA may increase by an area by which the intermediate area IA decreases.

Therefore, as the display area DA increases, a greater number of subpixels SP may be disposed.

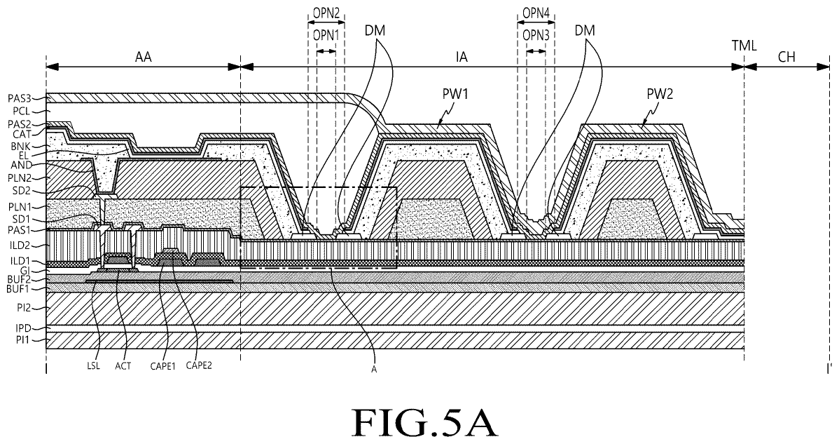

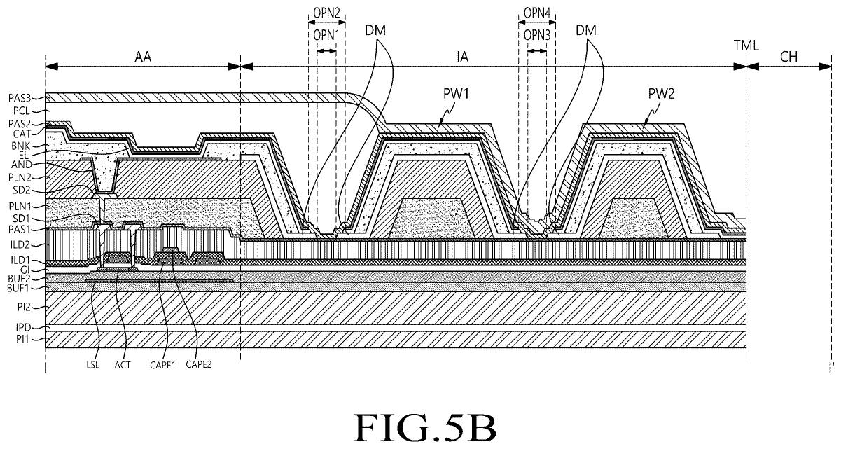

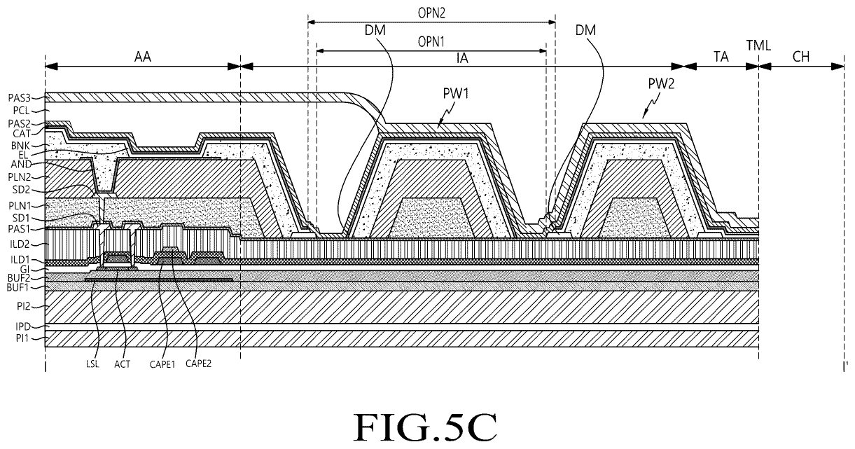

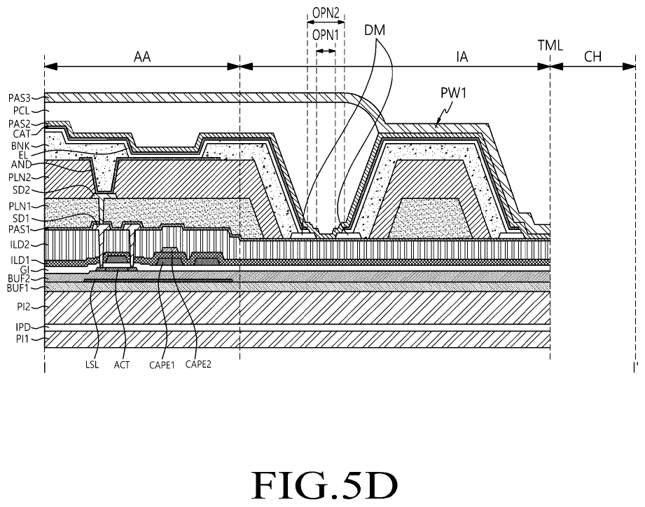

FIGS. 5A to 5D are cross-sectional views taken along the line I-I′ of FIG. 4A.

Referring to FIGS. 5A to 5D, a light emitting element and a transistor may be disposed on substrates PI1 and PI2 in an active area AA.

The substrates PI1 and PI2 may include a first substrate PI1 and a second substrate PI2.

A substrate light emitting layer IPD may be located between the first substrate PI1 and the second substrate PI2.

The substrate light emitting layer IPD may prevent moisture penetration.

A first buffer layer BUF1 may be formed on the second substrate PI2.

A light blocking layer LSL may be formed on the first buffer layer BUF1, and a second buffer layer BUF2 may be formed on the light blocking layer LSL.

Each of the first buffer layer BUF1 and the second buffer layer BUF2 may be formed of an inorganic insulating material, and may be composed of at least one insulating layer.

The light blocking layer LSL may be patterned in a photolithography process.

The light blocking layer LSL may include a light blocking pattern.

The light blocking pattern may block external light from radiating onto the active layer of a thin film transistor, thereby preventing photocurrent of the thin film transistor from being formed in an active area.

An active layer ACT may be formed of a semiconductor material on the second buffer layer BUF2, and may be patterned by a photolithography process.

The active layer ACT may be partially metallized by ion doping.

A metallized portion may be used as a jumper pattern which connects metal layers at some nodes of a circuit, thereby connecting components of the circuit.

A gate insulating layer GI may be formed on the second buffer layer BUF2 to cover the active layer ACT.

The gate insulating layer GI may be made of an inorganic insulating material.

A first storage capacitor electrode layer CAPE1 may be formed on the gate insulating layer GI.

The first storage capacitor electrode layer CAPE1 may be patterned by a photolithography process.

The first storage capacitor electrode layer CAPE1 may be used as a jumper pattern which connects patterns of a gate line, a gate electrode, the bottom electrode of a storage capacitor, the light blocking layer LSL and a second storage capacitor electrode layer CAPE2.

A first interlayer insulating layer ILD1 may be formed on the gate insulating layer GI to cover the first storage capacitor electrode layer CAPE1.

The second storage capacitor electrode layer CAPE2 may be formed on the first interlayer insulating layer ILD2, and a second interlayer insulating layer ILD2 may cover the second storage capacitor electrode layer CAPE2.

The second storage capacitor electrode layer CAPE2 may be patterned by a photolithography process.

The second storage capacitor electrode layer CAPE2 may include metal patterns such as the top electrode of the storage capacitor.

The first interlayer insulating layer ILD1 and the second interlayer insulating layer ILD2 may include an inorganic insulating material.

A first source drain electrode layer SD1 may be formed on the second interlayer insulating layer ILD2, and an inorganic insulating layer PAS1 and a first planarization layer PLN1 may be stacked on the first source drain electrode layer SD1.

A second source drain electrode layer SD2 may be formed on the first planarization layer PLN1.

The first planarization layer PLN1 and a second planarization layer PLN2 may be made of an organic insulating material that planarizes a surface.

The first source drain electrode layer SD1 may include a first electrode and a second electrode of a thin film transistor which are connected to the active pattern of the thin film transistor through contact holes passing through the second interlayer insulating layer ILD2.

Data lines DL and power wirings may be implemented with the first source drain electrode layer SD1 or the second source drain electrode layer SD2.

An anode electrode AND, which is the first electrode layer of the light emitting element ED, may be formed on the second planarization layer PLN2.

The anode electrode AND may be connected to the electrode of a driving thin film transistor through a contact hole passing through the second planarization layer PLN2.

The anode electrode AND may be made of a transparent or translucent electrode material.

A bank layer BNK may cover the anode electrode AND of the light emitting element ED.

The bank layer BNK may be formed as a pattern which defines a light emitting area through which light passes to the outside from each subpixel.

A light emitting layer EL may be formed in the light emitting area of each subpixel which is defined by the bank layer BNK.

A cathode electrode CAT, which is the second electrode layer of the light emitting element ED, may be formed on the entire surface of the display device 100 to cover the bank layer BNK and the light emitting layer EL.

An encapsulation layer may include inorganic encapsulation layers PAS2 and PAS3 and an organic encapsulation layer PCL therebetween.

A first inorganic encapsulation layer PAS2 may cover the cathode electrode CAT, and the organic encapsulation layer PCL may be formed on the first inorganic encapsulation layer PAS2.

The second inorganic encapsulation layer PAS3 may be formed on the organic encapsulation layer PCL.

Referring to FIGS. 5A to 5D, in the intermediate area IA, a dummy metal layer DM which has openings OPN1 and OPN3 may be formed on the inorganic insulating layer PAS1.

In the intermediate area IA, the light emitting layer EL which has openings may be formed on the dummy metal layer DM.

In the intermediate area IA, the cathode electrode CAT which has openings OPN2 and OPN4 may be formed on the light emitting layer EL.

Referring to FIGS. 5A to 5C, the openings OPN1 and OPN3 of the dummy metal layer DM may be referred to as a first opening OPN1 and a third opening OPN3, and the openings OPN2 and OPN4 of the cathode electrode CAT may be referred to as a second opening OPN2 and a fourth opening OPN4.

The second opening OPN2 may overlap the first opening OPN1, and the fourth opening OPN4 may overlap the third opening OPN3.

The first opening OPN1 and the third opening OPN3 may be covered by the first inorganic encapsulation layer PAS2 and the second inorganic encapsulation layer PAS3.

As the formation of a burr on the cathode electrode CAT is prevented, the reliability of the display device 100 may be improved.

The organic encapsulation layer PCL may be located on the first opening OPN1.

The first dam PW1 may be disposed between the first opening OPN1 and the third opening OPN3.

The second dam PW2 may be disposed between the third opening OPN3 and a transmission area TA.

Referring to FIGS. 5A to 5C, the first dam PW1 and the second dam PW2 may be located on the inorganic insulating layer PAS1.

The first dam PW1 and the second dam PW2 may include the first planarization layer PLN1 on the inorganic insulating layer PAS1, the second planarization layer PLN2 on the first planarization layer PLN1, and the bank layer BNK on the second planarization layer PLN2.

The first dam PW1 and the second dam PW2 may be covered by the encapsulation layers PAS2, PAS3 and PCL.

Referring to FIG. 5A, as an embodiment, the dummy metal layer DM which includes the first opening OPN1 and the dummy metal layer DM which includes the third opening OPN3 may be disposed to be spaced apart from each other.

However, the present disclosure is not necessarily limited thereto. As another embodiment, referring to FIG. 5B, the dummy metal layer DM which includes the first opening OPN1 may extend in the direction of the channel hole CH to be disposed along the upper surface of the second planarization layer PLN2, and may include the third opening OPN3 between the first dam PW1 and the second dam PW2.

As still another embodiment, referring to FIG. 5C, the first dam PW1 may be located in the first opening OPN1 of the dummy metal layer DM.

As the first dam PW1 is located in the first opening OPN1, the organic encapsulation layer PCL may overlap only a partial area of the first opening OPN1.

The dummy metal layer DM may include at least one of Ti, Al, Ag, Mg or indium tin oxide (ITO).

As yet still another example, referring to FIG. 5D, as cutting is performed between the first dam PW1 and the second dam PW2, the second dam PW2 may be removed and only the first dam PW1 may remain.

That is to say, a dam may not be additionally disposed between the first dam PW1 and the cutting line TML.

Referring to FIGS. 5A to 5C, the channel hole CH may be formed by cutting, along the cutting line TML, the first substrate PI1, the second substrate PI2, the substrate light emitting layer IPD, the first buffer layer BUF1, the second buffer layer BUF2, the gate insulating layer GI, the first interlayer insulating layer ILD1, the second interlayer insulating layer ILD2, the inorganic insulating layer PAS1, the light emitting layer EL, the cathode electrode CAT, the first inorganic encapsulation layer PAS2 and the second inorganic encapsulation layer PAS3.

Referring to FIG. 5D, the channel hole CH may be formed by cutting, along the cutting line TML, the first substrate PI1, the second substrate PI2, the substrate light emitting layer IPD, the first buffer layer BUF1, the second buffer layer BUF2, the gate insulating layer GI, the first interlayer insulating layer ILD1, the second interlayer insulating layer ILD2, the inorganic insulating layer PAS1, the first inorganic encapsulation layer PAS2 and the second inorganic encapsulation layer PAS3.

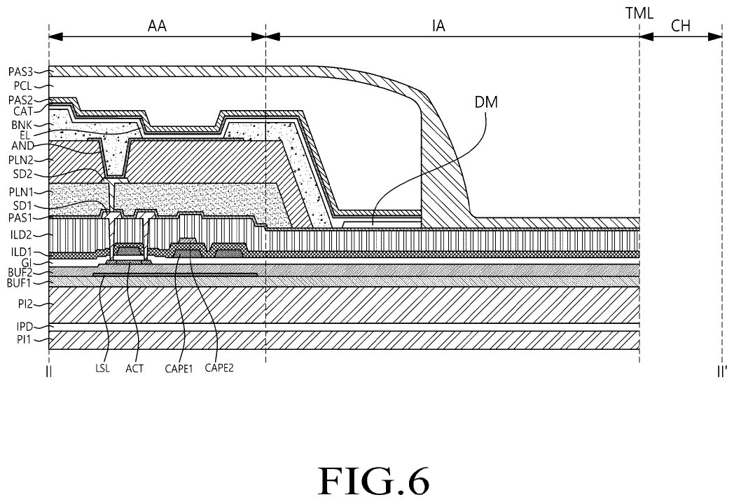

FIG. 6 is a cross-sectional view taken along the line II-II′ of FIG. 4B.

A light blocking layer LSL, a first substrate PI1, a second substrate PI2, a substrate light emitting layer IPD, a first buffer layer BUF1, a second buffer layer BUF2, a gate insulating layer GI, a first interlayer insulating layer ILD1, a second interlayer insulating layer ILD2, an active layer ACT, a first storage capacitor electrode layer CAPE1, a second storage capacitor electrode layer CAPE2, an inorganic insulating layer PAS1, a first source drain electrode layer SD1, a second source drain electrode layer SD2, a first planarization layer PLN1, a second planarization layer PLN2, an anode electrode AND, a light emitting layer EL, a cathode electrode CAT, a bank layer BNK, a first inorganic encapsulation layer PAS2, a second inorganic encapsulation layer PAS3 and an organic encapsulation layer PCL of FIG. 6 may be substantially the same as the light blocking layer LSL, the first substrate PI1, the second substrate PI2, the substrate light emitting layer IPD, the first buffer layer BUF1, the second buffer layer BUF2, the gate insulating layer GI, the first interlayer insulating layer ILD1, the second interlayer insulating layer ILD2, the active layer ACT, the first storage capacitor electrode layer CAPE1, the second storage capacitor electrode layer CAPE2, the inorganic insulating layer PAS1, the first source drain electrode layer SD1, the second source drain electrode layer SD2, the first planarization layer PLN1, the second planarization layer PLN2, the anode electrode AND, the light emitting layer EL, the cathode electrode CAT, the bank layer BNK, the first inorganic encapsulation layer PAS2, the second inorganic encapsulation layer PAS3 and the organic encapsulation layer PCL described above with reference to FIGS. 5A and 5B.

Referring to FIG. 6, in the intermediate area IA, a dummy metal layer DM may be located on the inorganic insulating layer PAS1.

The light emitting layer EL may cover an area of the dummy metal layer DM which overlaps the organic encapsulation layer PCL.

In other words, the light emitting layer EL may not cover an area of the dummy metal layer DM which does not overlap the organic encapsulation layer PCL.

The cathode electrode CAT may be disposed on the area of the dummy metal layer DM which overlaps the organic encapsulation layer PCL, and the encapsulation layers PAS2, PAS3 and PCL may be disposed on the cathode electrode CAT.

Referring to FIG. 6, the second inorganic encapsulation layer PAS3 among the encapsulation layers PAS2, PAS3 and PCL may cover the boundary between the area of the dummy metal layer DM which overlaps the organic encapsulation layer PCL and an area of the dummy metal layer DM which does not overlap the organic encapsulation layer PCL.

When the second inorganic encapsulation layer PAS3 is designed to have a structure which covers the boundary between the area of the dummy metal layer DM overlapping the organic encapsulation layer PCL and the area of the dummy metal layer DM not overlapping the organic encapsulation layer PCL, since a dam is removed in the intermediate area IA, the area of the intermediate area IA may be reduced, and thus, the area of the active area AA may relatively increase.

As the area of the active area AA increases, more subpixels SP may be disposed in the active area AA.

The dummy metal layer DM may include at least one of Ti, Al, Ag, Mg or ITO.

Referring to FIG. 6, the channel hole CH may be formed by cutting, along the cutting line TML, the first substrate PI1, the second substrate PI2, the substrate light emitting layer IPD, the first buffer layer BUF1, the second buffer layer BUF2, the gate insulating layer GI, the first interlayer insulating layer ILD1, the second interlayer insulating layer ILD2, the inorganic insulating layer PAS1 and the second inorganic encapsulation layer PAS3.

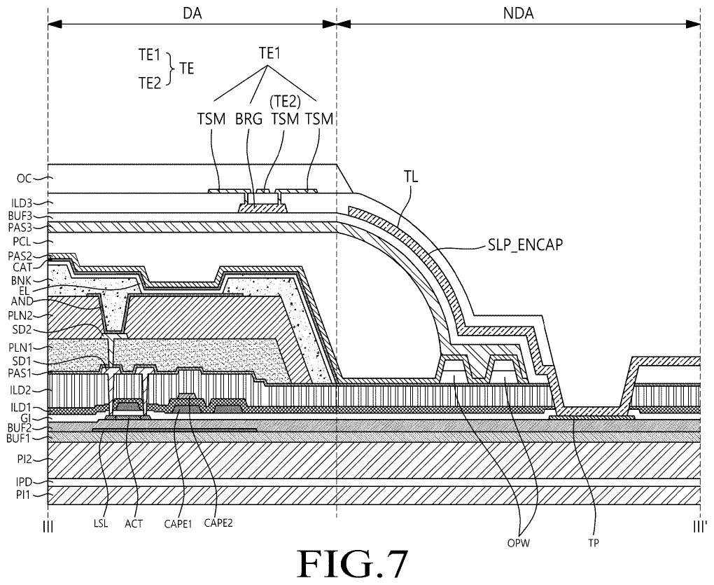

FIG. 7 is a cross-sectional view taken along the line III-III′ of FIG. 4A.

A light blocking layer LSL, a first substrate PI1, a second substrate PI2, a substrate light emitting layer IPD, a first buffer layer BUF1, a second buffer layer BUF2, a gate insulating layer GI, a first interlayer insulating layer ILD1, a second interlayer insulating layer ILD2, an active layer ACT, a first storage capacitor electrode layer CAPE1, a second storage capacitor electrode layer CAPE2, an inorganic insulating layer PAS1, a first source drain electrode layer SD1, a second source drain electrode layer SD2, a first planarization layer PLN1, a second planarization layer PLN2, an anode electrode AND, a light emitting layer EL, a cathode electrode CAT, a bank layer BNK, a first inorganic encapsulation layer PAS2, a second inorganic encapsulation layer PAS3 and an organic encapsulation layer PCL of FIG. 7 may be substantially the same as the light blocking layer LSL, the first substrate PI1, the second substrate PI2, the substrate light emitting layer IPD, the first buffer layer BUF1, the second buffer layer BUF2, the gate insulating layer GI, the first interlayer insulating layer ILD1, the second interlayer insulating layer ILD2, the active layer ACT, the first storage capacitor electrode layer CAPE1, the second storage capacitor electrode layer CAPE2, the inorganic insulating layer PAS1, the first source drain electrode layer SD1, the second source drain electrode layer SD2, the first planarization layer PLN1, the second planarization layer PLN2, the anode electrode AND, the light emitting layer EL, the cathode electrode CAT, the bank layer BNK, the first inorganic encapsulation layer PAS2, the second inorganic encapsulation layer PAS3 and the organic encapsulation layer PCL described above with reference to FIGS. 5A and 5B.

Referring to FIG. 7, a third buffer layer BUF3 may be disposed on the second inorganic encapsulation layer PAS3.

A plurality of touch electrodes TE may be included on the third buffer layer BUF3, and a sensor metal TSM and a bridge metal BRG may be included to form the plurality of touch electrodes TE.

In the embodiments of the present disclosure, the sensor metal TSM is also referred to as a sensor metal layer TSM, and the bridge metal BRG is also referred to as a bridge metal layer BRG.

Referring to FIG. 7, a third interlayer insulating layer ILD3 may be disposed on the third buffer layer BUF3, and an overcoat layer OC may be disposed on the third interlayer insulating layer ILD3.

The bridge metal BRG may be disposed between the third buffer layer BUF3 and the third interlayer insulating layer ILD3, and the sensor metal TSM may be disposed between the third interlayer insulating layer ILD3 and the overcoat layer OC.

Each of the plurality of touch electrodes TE may be configured with the sensor metal TSM.

Each of the plurality of touch electrodes TE may be a mesh-type electrode which has a plurality of openings.

The plurality of touch electrodes TE may include a first touch electrode TEL and a second touch electrode TE2.

The sensor metal TSM included in the first touch electrode TE1 may be electrically connected through the bridge metal BRG.

Namely, sensor metals TSM which are spaced apart from each other may be electrically connected by the bridge metal BRG to constitute one first touch electrode TE1.

The bridge metal BRG may be disposed on the third buffer layer BUF3, and the third interlayer insulating layer ILD3 may be disposed on the bridge metal BRG.

The sensor metal TSM may be disposed on the third interlayer insulating layer ILD3.

A portion of the sensor metal TSM may be connected to a corresponding bridge metal BRG through a hole of the third interlayer insulating layer ILD3.

Referring to FIG. 7, the sensor metal TSM and the bridge metal BRG may be disposed not to overlap the light emitting element ED.

The sensor metal TSM and the bridge metal BRG may overlap the bank layer BNK.

A plurality of sensor metals TSM may constitute one touch electrode TE, may be disposed in the form of a mesh, and may be electrically connected.

A portion of the sensor metal TSM and another portion of the sensor metal TSM may be electrically connected through the bridge metal BRG to constitute one touch electrode TE.

The overcoat layer OC may be disposed to cover the sensor metal TSM and the bridge metal BRG.

Referring to FIG. 7, a touch line TL may electrically connect the touch electrode TE and a touch pad TP.

The touch line TL may include at least one of the sensor metal TSM and the bridge metal BRG.

When the display panel 110 is a type that incorporates a touch sensor, the touch line TL may extend along an outer sloped surface SLP_ENCAP of the second inorganic encapsulation layer PAS3, and may extend over the outer dam OPW to the touch pad TP which is disposed in the non-display area NDA.

The outer dam OPW may include two partition walls which surround the outside of the display area DA, but is not limited thereto.

The outer dam OPW is disposed in the non-display area NDA.

Referring to FIG. 7, as the dummy metal layer DM of FIGS. 5A to 5D is disposed between the display area DA and the outer dam OPW, a structure in which the light emitting layer EL is cut using a laser may be formed, thereby securing reliability, but the present disclosure is not limited thereto.

Alternatively, referring to FIG. 7, as the dummy metal layer DM is disposed under the outer dam OPW as in FIG. 6, the entirety or a part of the outer dam OPW may be removed using a laser, whereby it is possible to reduce the area of the non-display area NDA and increase the area of the display area DA.

As the area of the display area DA increases, more subpixels SP may be disposed in the display area DA.

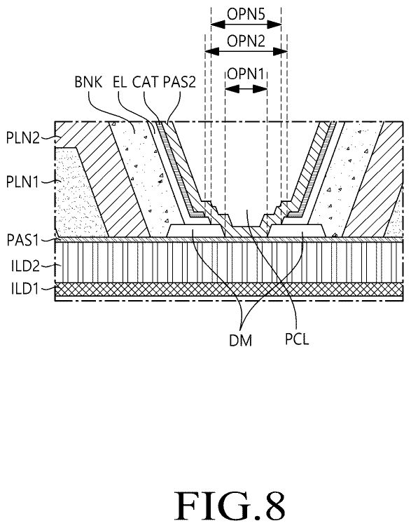

FIG. 8 is an enlarged sectional view of the part A of FIG. 5A.

A first interlayer insulating layer ILD1, a second interlayer insulating layer ILD2, a first planarization layer PLN1, a second planarization layer PLN2, a bank layer BNK, a dummy metal layer DM, a light emitting layer EL, a cathode electrode CAT, a first inorganic encapsulation layer PAS2 and an organic encapsulation layer PCL of FIG. 8 may be substantially the same as the first interlayer insulating layer ILD1, the second interlayer insulating layer ILD2, the first planarization layer PLN1, the second planarization layer PLN2, the bank layer BNK, the dummy metal layer DM, the light emitting layer EL, the cathode electrode CAT, the first inorganic encapsulation layer PAS2 and the organic encapsulation layer PCL described above with reference to FIG. 5A.

Referring to FIG. 8, the light emitting layer EL may include a fifth opening OPN5 which overlaps a first opening OPN1.

The cathode electrode CAT may include a second opening OPN2 which overlaps the fifth opening OPN5.

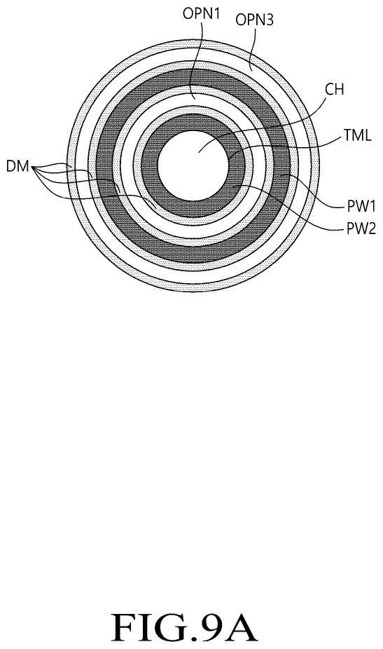

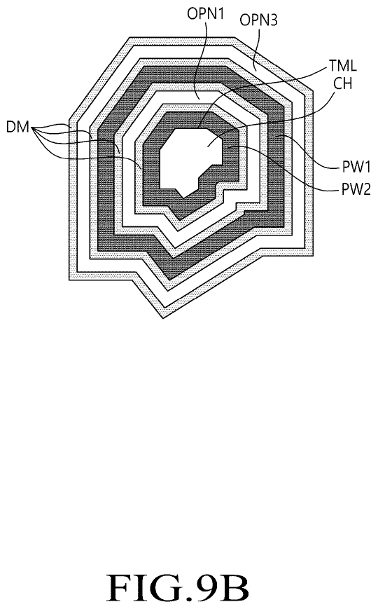

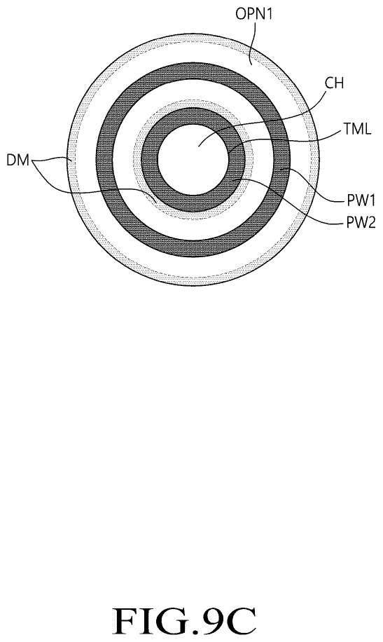

FIGS. 9A to 9C are plan views showing at least one dam shown in FIG. 4A.

A first dam PW1 and a second dam PW2 of FIGS. 9A to 9C may be substantially the same as the first dam PW1 and the second dam PW2 described above with reference to FIG. 4A.

In addition, a dummy metal layer DM of FIGS. 9A to 9C may be substantially the same as the dummy metal layer DM described above with reference to FIG. 5A.

Referring to FIGS. 9A to 9C, the first dam PW1 and the second dam PW2 may be disposed in simple closed curve shapes which surround the channel hole CH, to be spaced apart from each other in the intermediate area IA.

FIGS. 9A and 9C show that the first dam PW1 and the second dam PW2 are disposed to be spaced apart from each other in ring shapes which surround the ring-shaped channel hole CH.

FIG. 9B shows that the first dam PW1 and the second dam PW2 are disposed to be spaced apart from each other in simple closed curve shapes which surround the channel hole CH having a simple closed curve shape.

Referring to FIGS. 9A and 9B, a first opening OPN1 may be located between the first dam PW1 and the second dam PW2.

The second dam PW2 may be located between the first opening OPN1 and a third opening OPN3.

Referring to FIG. 9C, the second dam PW2 may be located within the first opening OPN1.

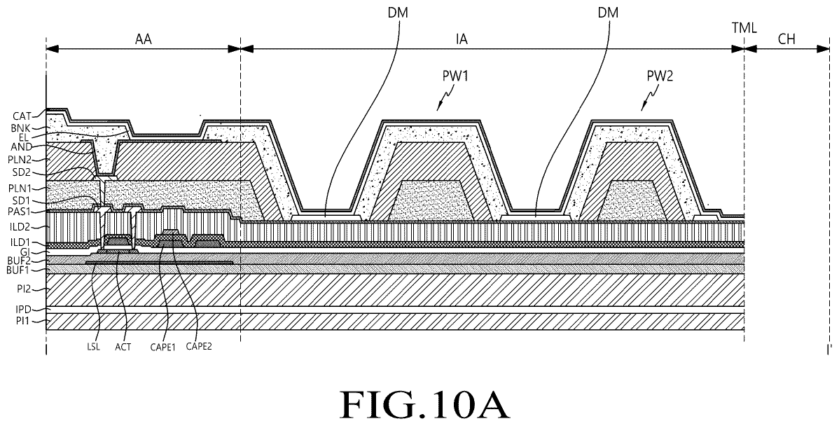

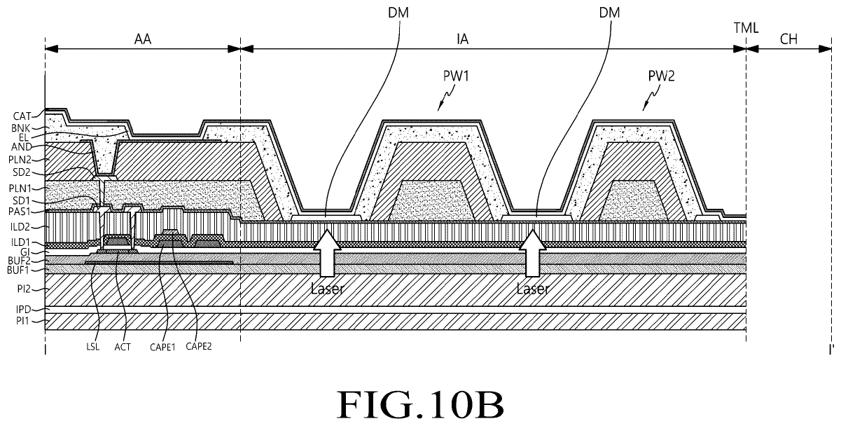

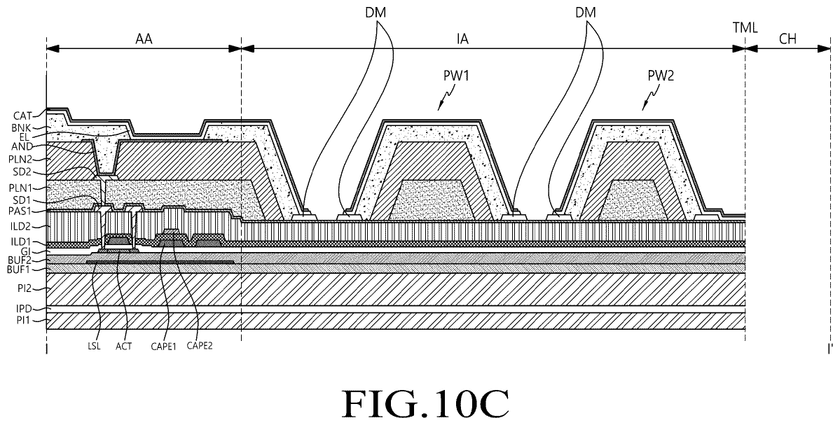

FIGS. 10A to 10C are cross-sectional views simply showing a process for forming a partial area of the display panel according to the embodiments of the present disclosure.

FIGS. 10A to 10C show, as an example, a process for forming a partial area of the display panel of FIG. 5A.

Referring to FIG. 10A, in the intermediate area IA, the dummy metal layer DM may be disposed between the inorganic insulating layer PAS1 and the light emitting layer EL.

The dummy metal layer DM may be disposed between the active area AA and the first dam PW1 or between the first dam PW1 and the second dam PW2.

Referring to FIG. 10B, a laser having a pulse width smaller than the width of the dummy metal layer DM may be irradiated to the underside of the dummy metal layer DM.

The width of the dummy metal layer DM should be larger than the pulse width of the laser so that the dummy metal layer DM suppresses the reaction between the laser and the cathode electrode CAT, thereby reducing foreign substances generated during processing of the cathode electrode CAT and suppressing the formation of a burr on the cathode electrode CAT.

Referring to FIG. 10C, when the laser is irradiated, a display panel may be manufactured without forming a burr on the cathode electrode CAT as in FIG. 5A.

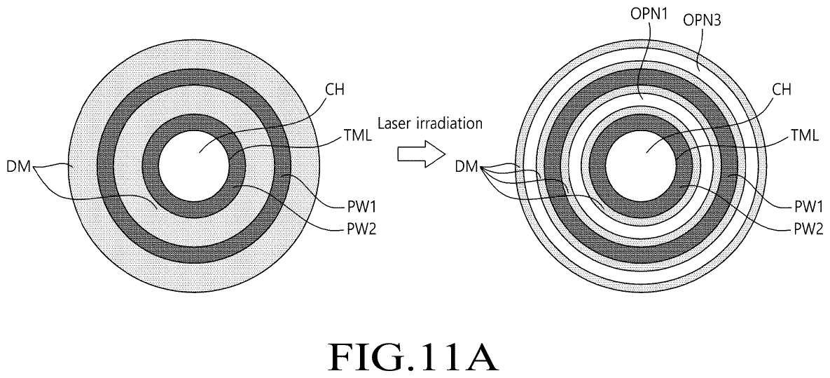

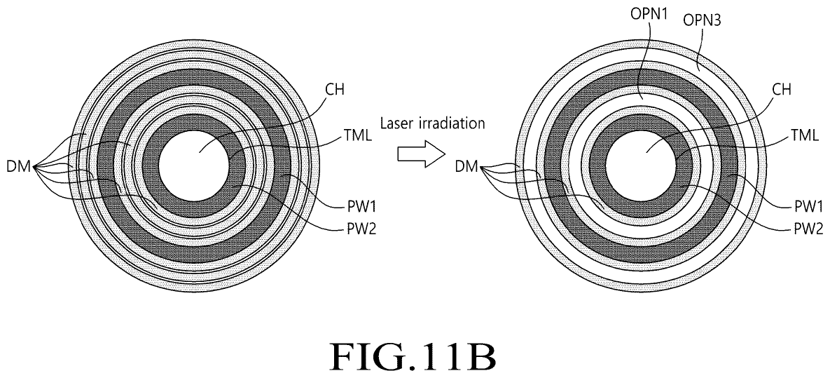

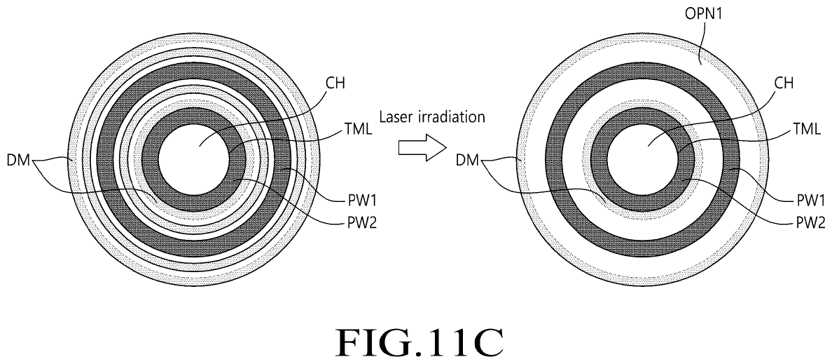

FIGS. 11A to 11C are plan views simply showing a process for forming a partial area of the display panel according to the embodiments of the present disclosure.

Referring to FIG. 11A, the dummy metal layer DM may be disposed in ring shapes along the first dam PW1 and the second dam PW2.

When a laser having a pulse width smaller than the width of the dummy metal layer DM is irradiated, the dummy metal layer DM which has the first opening OPN1 and the third opening OPN3 may be formed.

Referring to FIG. 11B, the dummy metal layer DM may be disposed in ring shapes along the first dam PW1 and the second dam PW, and at least one dummy metal layer DM of a ring shape may be disposed to be spaced apart from the dummy metal layer DM.

That is to say, the at least one dummy metal layer DM may be both island and ring-shaped.

Referring to FIG. 11B, by irradiating a laser along the at least one dummy metal layer DM which is both island and ring-shaped, the dummy metal layer DM which has the first opening OPN1 and the third opening OPN3 may be formed.

However, the disposition of a dummy metal layer DM which is island and ring-shaped is not limited to thereto, and as shown in FIG. 11C, at least one dummy metal layer DM may be disposed to be spaced apart from the dummy metal layer DM and the first dam PW1.

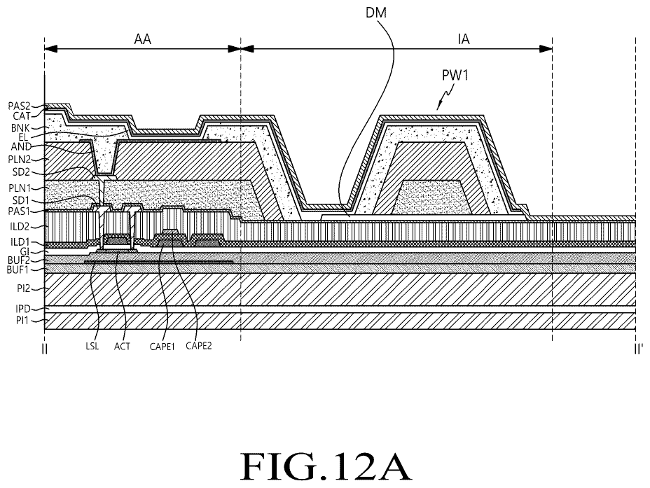

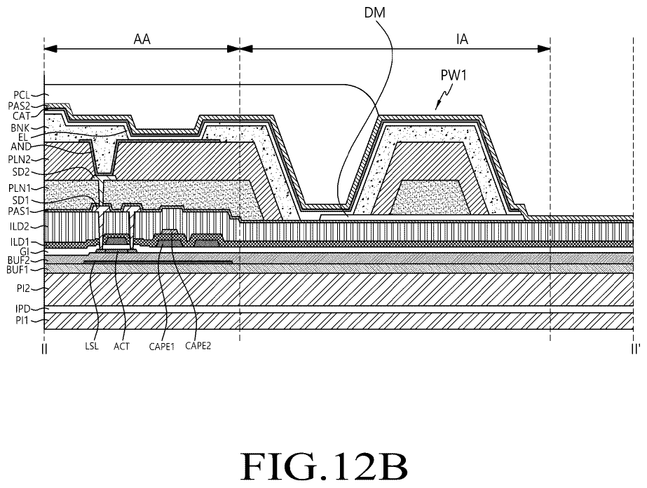

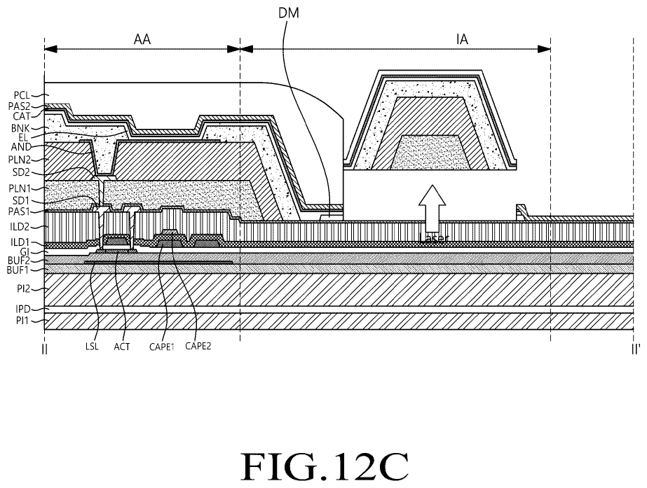

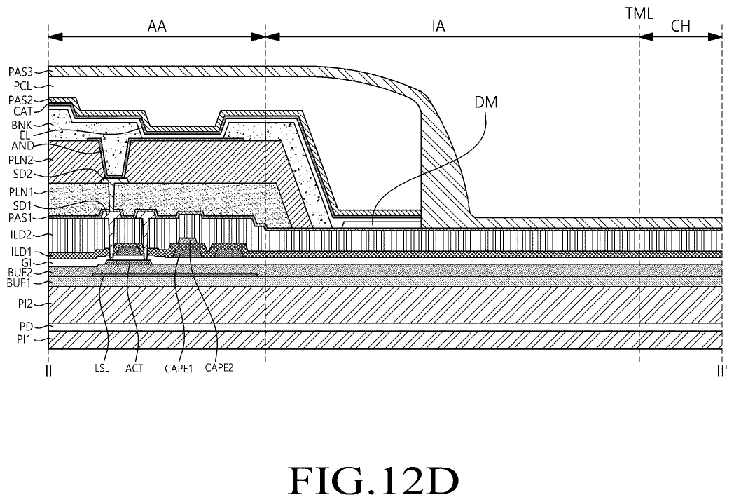

FIGS. 12A to 12D are cross-sectional views simply showing a process for forming a partial area of the display panel according to the embodiments of the present disclosure.

FIGS. 12A to 12D may show a process for forming a partial area of the display panel of FIG. 6.

Referring to FIG. 12A, the dummy metal layer DM may be located between the first planarization layer PLN1 of the first dam PW1 and the inorganic insulating layer PAS1.

Referring to FIG. 12B, the organic encapsulation layer PCL may be formed on the first inorganic encapsulation layer PAS2 to overlap at least a portion of the dummy metal layer DM.

Referring to FIG. 12C, after forming the organic encapsulation layer PCL, a laser may be irradiated to the underside of the dummy metal layer DM before forming the second inorganic encapsulation layer PAS3, to remove the first dam PW1 located on the dummy metal layer DM.

Referring to FIG. 12D, after removing the first dam PW1 located on the dummy metal layer DM using a laser, the second inorganic encapsulation layer PAS3 may be formed to cover the boundary between the area of the dummy metal layer DM overlapping the organic encapsulation layer PCL and an area of the dummy metal layer DM not overlapping the organic encapsulation layer PCL.

After forming the second inorganic encapsulation layer PAS3, in order to form the channel hole CH, the first substrate PI1, the second substrate PI2, the substrate light emitting layer IPD, the first buffer layer BUF1, the second buffer layer BUF2, the gate insulating layer GI, the first interlayer insulating layer ILD1, the second interlayer insulating layer ILD2, the inorganic insulating layer PAS1 and the second inorganic encapsulation layer PAS3 may be cut along the cutting line TML.

Referring to FIGS. 12A to 12D, as the first dam PW1 is removed in the intermediate area IA, the area of the intermediate area IA may decrease, and thus, the area of the active area AA may relatively increase.

Brief description of the embodiments of the present disclosure described above is as follows.

A display device according to embodiments of the present disclosure may include a substrate; an opening area; a display area which surrounds the opening area; an intermediate area between the opening area and the display area; an insulating layer located in the intermediate area on the substrate; a first metal layer located on the insulating layer and including at least one first opening, the at least one first opening being located in the intermediate area; a second metal layer located on the first metal layer in the intermediate area and including at least one second opening, the at least one second opening being disposed in an area including an area overlapping the at least one first opening; and an organic encapsulation layer located on the insulating layer and at least partially overlapping the at least one first opening.

In the display device according to the embodiments of the present disclosure, an inorganic encapsulation layer may be located on the organic encapsulation layer, the intermediate area may include a first intermediate area which overlaps the organic encapsulation layer and a second intermediate area which does not overlap the organic encapsulation layer, and the display device may further include a first metal layer located on the insulating layer and including at least one third opening, the at least one third opening being located in the second intermediate area; and a second metal layer located on the first metal layer in the second intermediate area and including at least one fourth opening, the at least one fourth opening being disposed in an area including an area overlapping the at least one third opening.

In the display device according to the embodiments of the present disclosure, the display device may further include a bank layer located on the insulating layer and the first metal layer and covering at least a portion of the first metal layer; and a light emitting layer located on the bank layer and the first metal layer and including at least one fifth opening, the at least one fifth opening being located in an area including an area overlapping the at least one first opening.

In the display device according to the embodiments of the present disclosure, the display device may further include a dam located between the at least one first opening and the at least one third opening, located on the insulating layer, and including a planarization layer.

In the display device according to the embodiments of the present disclosure, the first metal layer may cover the planarization layer.

In the display device according to the embodiments of the present disclosure, the organic encapsulation layer may overlap a portion of the at least one first opening.

In the display device according to the embodiments of the present disclosure, the first metal layer may include at least one of Ti, Al, Ag, Mg or ITO.

In the display device according to the embodiments of the present disclosure, the second metal layer may include at least one of transparent conductive oxide or translucent metal.

A display device according to embodiments of the present disclosure may include a substrate; an opening area; a display area which surrounds the opening area; an intermediate area between the opening area and the display area; an outer area which surrounds an outside of the display area; at least one first dam located on the substrate and disposed in the outer area; and at least one second dam located on the substrate, disposed in the intermediate area and including a dummy electrode which is located at a same layer as a cathode electrode disposed in the display area.

In the display device according to the embodiments of the present disclosure, the display device may further include an encapsulation layer located on the substrate, and including a first inorganic encapsulation layer on the substrate, an organic encapsulation layer on the first inorganic encapsulation layer and a second inorganic encapsulation layer on the organic encapsulation layer, wherein the intermediate area includes a first part which is located between the display area and the at least one second dam and a second part which is located between the at least one second dam and the opening area, and wherein the organic encapsulation layer covers at least a portion of the first part and does not cover the second part.

In the display device according to the embodiments of the present disclosure, a third dam may be disposed in the first part, and the organic encapsulation layer may cover between the display area and the third dam and may not cover between the third dam and the at least one second dam.

In the display device according to the embodiments of the present disclosure, the at least one second dam may have a closed curve shape.

In the display device according to the embodiments of the present disclosure, the at least one second dam may have a ring shape.

A display device according to embodiments of the present disclosure may include a substrate; an opening area; a display area which surrounds the opening area; an intermediate area between the opening area and the display area; an insulating layer located in the intermediate area on the substrate; an encapsulation layer located on the insulating layer, located in the intermediate area, and including a first part which includes an organic encapsulation layer and a second part which does not include the organic encapsulation layer; a first metal layer located in the first part and located between the insulating layer and the organic encapsulation layer; and a second metal layer located in the first part and located between the first metal layer and the organic encapsulation layer.

In the display device according to the embodiments of the present disclosure, the display device may further include a light emitting layer located in the first part, located on the insulating layer, and covering the first metal layer.

In the display device according to the embodiments of the present disclosure, the display device may further include an inorganic encapsulation layer located in the first part and located on the organic encapsulation layer, wherein the inorganic encapsulation layer covers the organic encapsulation layer located in the first part and a boundary between the first part and the second part.

In the display device according to the embodiments of the present disclosure, the first metal layer may include at least one of Ti, Al, Ag, Mg or ITO.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. The scope of protection of the present disclosure should be construed based on the following claims, and all technical features within the scope of equivalents thereof should be construed as being included within the scope of the present disclosure.

What is claimed is:

1. A display device, comprising:
a substrate;
an opening area;
a display area which surrounds the opening area;
an intermediate area between the opening area and the display area;
an insulating layer located in the intermediate area on the substrate;
a first metal layer located on the insulating layer and including at least one first opening, the at least one first opening being located in the intermediate area;
a second metal layer located on the first metal layer in the intermediate area and including at least one second opening, the at least one second opening being disposed in an area including an area overlapping the at least one first opening; and
an organic encapsulation layer located on the insulating layer and at least partially overlapping the at least one first opening.

2. The display device of claim 1,
wherein an inorganic encapsulation layer is located on the organic encapsulation layer,
wherein the intermediate area includes a first intermediate area which overlaps the organic encapsulation layer and a second intermediate area which does not overlap the organic encapsulation layer, and
wherein the display device further comprises:
the first metal layer further includes at least one third opening, the at least one third opening being located in the second intermediate area; and
the second metal layer further includes at least one fourth opening in the second intermediate area, the at least one fourth opening being disposed in an area including an area overlapping the at least one third opening.

3. The display device of claim 1, further comprising:
a bank layer located on the insulating layer and the first metal layer and covering at least a portion of the first metal layer; and
a light emitting layer located on the bank layer and the first metal layer and including at least one fifth opening, the at least one fifth opening being located in an area including an area overlapping the at least one first opening.

4. The display device of claim 2, further comprising:
a dam located between the at least one first opening and the at least one third opening, located on the insulating layer, and including a planarization layer.

5. The display device of claim 4, wherein the first metal layer covers the planarization layer.

6. The display device of claim 1, wherein the organic encapsulation layer overlaps a portion of the at least one first opening.

7. The display device of claim 1, wherein the first metal layer includes at least one of Ti, Al, Ag, Mg or ITO.

8. The display device of claim 1, wherein the second metal layer includes at least one of transparent conductive oxide or translucent metal.

9. A display device, comprising:
a substrate;
an opening area;
a display area which surrounds the opening area;
an intermediate area between the opening area and the display area;
an outer area which surrounds an outside of the display area;
at least one first dam located on the substrate and disposed in the outer area; and
at least one second dam located on the substrate, disposed in the intermediate area and including a dummy electrode which is located at a same layer as a cathode electrode disposed in the display area.

10. The display device of claim 9, further comprising:
an encapsulation layer located on the substrate, and including a first inorganic encapsulation layer on the substrate, an organic encapsulation layer on the first inorganic encapsulation layer and a second inorganic encapsulation layer on the organic encapsulation layer,
wherein the intermediate area includes a first part which is located between the display area and the at least one second dam and a second part which is located between the at least one second dam and the opening area, and
wherein the organic encapsulation layer covers at least a portion of the first part and does not cover the second part.

11. The display device of claim 10, wherein
a third dam is disposed in the first part, and
the organic encapsulation layer covers between the display area and the third dam, and does not cover between the third dam and the at least one second dam.

12. The display device of claim 10, wherein the at least one second dam has a closed curve shape.

13. The display device of claim 12, wherein the at least one second dam has a ring shape.

14. A display device, comprising:
a substrate;
an opening area;
a display area which surrounds the opening area;
an intermediate area between the opening area and the display area;
an insulating layer located in the intermediate area on the substrate;
an encapsulation layer located on the insulating layer, located in the intermediate area, and including a first part which includes an organic encapsulation layer and a second part which does not include the organic encapsulation layer;
a first metal layer located in the first part and located between the insulating layer and the organic encapsulation layer; and
a second metal layer located in the first part and located between the first metal layer and the organic encapsulation layer.

15. The display device of claim 14, further comprising:
a light emitting layer located in the first part, located on the insulating layer, and covering the first metal layer.

16. The display device of claim 15, further comprising:
an inorganic encapsulation layer located in the first part and located on the organic encapsulation layer,
wherein the inorganic encapsulation layer covers the organic encapsulation layer located in the first part and a boundary between the first part and the second part.

17. The display device of claim 14, wherein the first metal layer includes at least one of Ti, Al, Ag, Mg or ITO.
